(19) United States
(12) Patent Application Publication
(10) Pub. No.: US 2026/0195511 A1
(43) Pub. Date: Jul. 9, 2026

(54) High Performance and Grid Computing with Multi-Channel Data Distributor Quality of Service

(71) Applicant: Saudi Arabian Oil Company, Dhahran (SA)

(72) Inventor: Raed Abdullah AlShaikh, Dhahran (SA)

(73) Assignee: Saudi Arabian Oil Company, Dhahran (SA)

(21) Appl. No.: 19/010,842

(22) Filed: Jan. 6, 2025

(51) Int. Cl. G06F 30/28

(52) U.S. Cl. CPC G06F 30/28

(57) ABSTRACT

A new and improved technique for computerized processing of data for exploration and production of hydrocarbons and reservoir simulations that includes a multi-channel quality of service (QoS) in a group of high performance computing (HPC) clusters (which may collectively be referred to as a “data processing system”). The data processing system may be logically segregated into several logical subclusters and may have several publisher nodes, controlled by a master scheduler, serving several groups of processor nodes (the subscriber nodes) that execute different processing applications independently of each other. Multiple datawriters (DW) may send data through multiple channels of compute nodes, whenever there is a free master node. The multi-channels are established and take place as part of the multi-channel quality of service (QoS) settings.

### BACKGROUND

### Field of the Disclosure

The present disclosure generally relates to high performance and grid computing of data for exploration and production of hydrocarbons, such as computerized simulation of hydrocarbon reservoirs in the earth, geological modeling, and processing of seismic survey data. More specifically, embodiments of the disclosure relate to multi-channel data distributor quality of service (QoS) control of such computing.

### Description of the Related Art

In the oil and gas industries, massive amounts of data are required to be processed for computerized simulation, modeling and analysis for exploration and production purposes. For example, the development of underground hydrocarbon reservoirs typically includes development and analysis of computer simulation models of the reservoir. These underground hydrocarbon reservoirs are typically complex rock formations which contain both a petroleum fluid mixture and water. The reservoir fluid content usually exists in two or more fluid phases. The petroleum mixture in reservoir fluids is produced by wells drilled into and completed in these rock formations.

A geologically realistic model of the reservoir, and the presence of its fluids, also helps in forecasting the optimal future oil and gas recovery from hydrocarbon reservoirs. Oil and gas companies have come to depend on geological models as an important tool to enhance the ability to exploit a petroleum reserve. However, geological models of reservoirs and oil/gas fields have become increasingly large and complex.

### SUMMARY

In complex simulation and geological models, the reservoir is organized into a number of individual cells. Seismic data with increasing accuracy has permitted the cells to be on the order of 25 meters areal (x and y axis) intervals. For what are known as giant reservoirs, the number of cells is in the least hundreds of millions, and reservoirs of what is known as giga-cell size (a billion cells or more) are encountered.

Similar considerations of data volume are also present in seismic data processing. Seismic data obtained from surveys over large areas of the earth's surface such as above giant reservoirs, has been acquired and made available in increased volumes. In processing vast amounts of data of all three of the types described above, processing time was an important consideration.

Three types of computer systems have been available for processing the vast amounts of data of the types encountered in petroleum exploration and production. These are supercomputers, high performance computing (HPC) and grid computing. Typically, supercomputers are specially designed for particular calculation intensive tasks. An HPC system takes the form of a group of powerful workstations or servers, joined together as a network to function as one supercomputer. Grid computing involves a more loosely coupled, heterogeneous and often dispersed network of workstations or servers than HPC.

So far as is known, existing distributed memory HPC and grid computing systems did not provide proper quality of service (QoS) based communication because of two limitations. First, standard communication libraries such as Message Passing Interface (MPI) and Parallel Virtual Machine (PVM) did not provide a capability for applications to specify service quality for computation and communication. Second, modern high-speed interconnects such as InfiniBand®, Myrinet, Quadrics and Gigabit Ethernet were optimized for performance rather than for predictability of communication latency and bandwidth.

There has been, so far as is known, little attention given to QoS control in high performance and grid computing. HPC users have witnessed a dramatic increase in performance over the last ten years with regard to the HPC systems. What used to take one month of HPC computation time in the ten years ago, is now taking only a few hours to run in current systems.

In view of this, the simplest remedy to users for a data accuracy failure rate during a routine computation run has been resubmitting the processing data run after disregarding or offlining (or what is known as fencing) the problematic node/core. However, the hours of the crashed job were thus discarded and wasted. Moreover, in the case of a more extensive data processing run which would require several days or even weeks to perform, resubmitting the entire data set for processing was required. However, this approach was duplicative and time-consuming.

Another issue with traditional Performance Computing Clusters, especially in data centers with multiple (HPCs), it is often found that some clusters are kept 100% utilized, since there is enough workload on them, while others may have completed their jobs, and thus staying idle, until the next batch job is submitted to these idle HPC clusters. This misdistribution of jobs happens because users often statically pre-designate their subclusters to certain types of jobs (for example, some subclusters to run Seismic jobs only, and others to run Reservoir Simulation jobs).

To address cluster utilization issues, organizations statically and manually route jobs through their multiple clusters, and check whenever there is a free subcluster, they balance the batch jobs between them. Other organizations use automated job schedulers; however, these schedulers do not use QoS characteristics and may not sufficiently address cluster utilization in certain environments.

In one embodiment, a method of computerized processing of data for exploration and production of hydrocarbons in a data processing system is provided. The data processing system includes a data memory, a plurality of subclusters, each of the plurality of subclusters having a respectively plurality of master nodes and a respective plurality of processor nodes that each receive data from the respectively plurality of master nodes, a plurality of publishing nodes, and a master scheduler. The method includes identifying, via the master scheduler, an idle publishing node of the plurality of publishing nodes, establishing a connection between the identified publishing node and a designated processor node of a select subcluster of the plurality of subclusters via a designated master node of the select subcluster, such that the establishing includes initiating a channel number for a communication channel between the designated master node and the identified publishing node. The method also includes assigning, via the master scheduler, data to be processed to the identified publishing node, transmitting the data from the identified publishing node to the designated processor node via the communication channel, and processing the data in the designated processor node. Additionally, the method includes transmitting the processed data to the designated master node and assembling in the data memory of the data processing system the processed data transmitted from the designated processor node.

In some embodiments, the method includes determining that no more data is to be processed by the designated processor node and reporting the determination to the master scheduler. In some embodiments, the data includes a reservoir simulation model. In some embodiments, the data includes a geological model of the reservoir. In some embodiments, the data includes a seismic survey of the earth in the reservoir. In some embodiments, the data processing system further includes a data display and the method includes forming an output display of the processed data. In some embodiments, the designated processor node is established as a datareader for receiving and processing selected ones of different sets of the data as domains transmitted by the identified publishing node.

In another embodiment, a data storage device having stored in a computer readable medium computer operable instructions for causing a data processing system to perform computerized processing of data for exploration and production of hydrocarbons is provided. The data processing system includes a data memory, a plurality of subclusters, each of the plurality of subclusters having a respectively plurality of master nodes and a respective plurality of processor nodes that each receive data from the respectively plurality of master nodes, a plurality of publishing nodes, and a master scheduler, the instructions stored in the data storage device causing the data processing system to perform operations that include identifying, via the master scheduler, an idle publishing node of the plurality of publishing nodes, establishing a connection between the identified publishing node and a designated processor node of a select subcluster of the plurality of subclusters via a designated master node of the select subcluster, such that the establishing includes initiating a channel number for a communication channel between the designated master node and the identified publishing node. The operations also include assigning, via the master scheduler, data to be processed to the identified publishing node, transmitting the data from the identified publishing node to the designated processor node via the communication channel, and processing the data in the designated processor node. Additionally, the operations include transmitting the processed data to the designated master node and assembling in the data memory of the data processing system the processed data transmitted from the designated processor node.

In some embodiments, the operations include determining that no more data is to be processed by the designated processor node and reporting the determination to the master scheduler. In some embodiments, the data includes a reservoir simulation model. In some embodiments, the data includes a geological model of the reservoir. In some embodiments, the data includes a seismic survey of the earth in the reservoir. In some embodiments, the data processing system further includes a data display and the operations include forming an output display of the processed data. In some embodiments, the designated processor node is established as a datareader for receiving and processing selected ones of different sets of the data as domains transmitted by the identified publishing node.

In another embodiment, a data processing system for computerized processing of data for exploration and production of hydrocarbons is provided. The data processing system includes a data memory, and a plurality of subclusters, each of the plurality of subclusters having a respectively plurality of master nodes and a respective plurality of processor nodes that each receive data from the respectively plurality of master nodes. The data processing system also includes a plurality of publishing nodes, a master scheduler, and a computer readable medium having computer operable instructions for causing the data processing system to perform operations that include identifying, via the master scheduler, an idle publishing node of the plurality of publishing nodes, establishing a connection between the identified publishing node and a designated processor node of a select subcluster of the plurality of subclusters via a designated master node of the select subcluster, such that the establishing includes initiating a channel number for a communication channel between the designated master node and the identified publishing node. The operations also include assigning, via the master scheduler, data to be processed to the identified publishing node, transmitting the data from the identified publishing node to the designated processor node via the communication channel, and processing the data in the designated processor node. Additionally, the operations include transmitting the processed data to the designated master node and assembling in the data memory of the data processing system the processed data transmitted from the designated processor node.

In some embodiments, the operations include determining that no more data is to be processed by the designated processor node and reporting the determination to the master scheduler. In some embodiments, the data includes a reservoir simulation model. In some embodiments, the data includes a geological model of the reservoir. In some embodiments, the data includes a seismic survey of the earth in the reservoir. In some embodiments, the data processing system further includes a data display and the operations include forming an output display of the processed data. In some embodiments, the designated processor node is established as a datareader for receiving and processing selected ones of different sets of the data as domains transmitted by the identified publishing node.

### BRIEF DESCRIPTION OF THE DRAWINGS

FIG. 1 is a block diagram of elements of an HPC system that may implement a multi-channel QoS in accordance with an embodiment of the disclosure;

FIG. 2 is a flowchart of a process for multi-channel quality of service (QoS) in accordance with an embodiment of the disclosure; and

FIG. 3 is a block diagram of a data processing system in accordance with an embodiment of the disclosure.

### DETAILED DESCRIPTION

The present disclosure will be described more fully with reference to the accompanying drawings, which illustrate embodiments of the disclosure. This disclosure may, however, be embodied in many different forms and should not be construed as limited to the illustrated embodiments. Rather, these embodiments are provided so that this disclosure will be thorough and complete, and will fully convey the scope of the disclosure to those skilled in the art.

Embodiments of the disclosure related to high performance computing of data for exploration and production of hydrocarbons, such as computerized simulation of hydrocarbon reservoirs in the earth, geological modeling, processing of seismic survey data, and other types of data gathered and processed to aid in the exploration and production of hydrocarbons. For the purposes of the present disclosure, the foregoing types of data are referred to herein as exploration and production data. The present disclosure is particularly adapted for processing exploration and production data where vast amounts of such data are present, such as in or around what are known as giant reservoirs or giga-reservoirs.

Embodiments of disclosure provide a new and improved technique for computerized processing in a data processing system of data for exploration and production of hydrocarbons and reservoir simulations. Embodiments of the disclosure may be implemented in a data center having multiple but segregated High Performance Computing (HPC) clusters, with varying utilization percentages for each subcluster while at the same time maintaining a QoS established between the datawriters and datareaders of the systems.

Embodiments of the disclosure include a multi-channel quality of service (QoS) in a group of high performance computing (HPC) clusters (which may collectively be referred to as a “data processing system”). The data processing system may be logically segregated into several “logical subclusters.” As described herein, the data processing system may have several publisher nodes, controlled by a master scheduler, serving several groups of processor nodes (the subscriber nodes) that execute different processing applications independently of each other. Multiple datawriters (DW) may send data through multiple channels of compute nodes, whenever there is a free master node. The multi-channels are established and take place as part of the multi-channel quality of service (QoS) settings described herein.

The multi-channel quality of services (QoS) according to the present disclosure may allow the data processing system to run more than one simulation or seismic applications, based on the multi-channel QoS. For example, in some embodiments, 10 subclusters (master nodes and processing nodes (“datareaders”)) of different vendors, make and kinds, may be internetworked together to be in the data readers and may wait for the data to be received from the Datawriters via the master nodes. Once the master scheduler sends data, a datawriter finds a subcluster that is idle through its master node, and initiates a channel of communication with the datareader of that subcluster. The master scheduler monitors the progress and determines where there is any datawriter completing its job, in order to provide it with a new set of seismic data, reservoir simulation data, or other data to be processed. Again, the master scheduler searches for a subcluster to allocate the empty one to establish the channel.

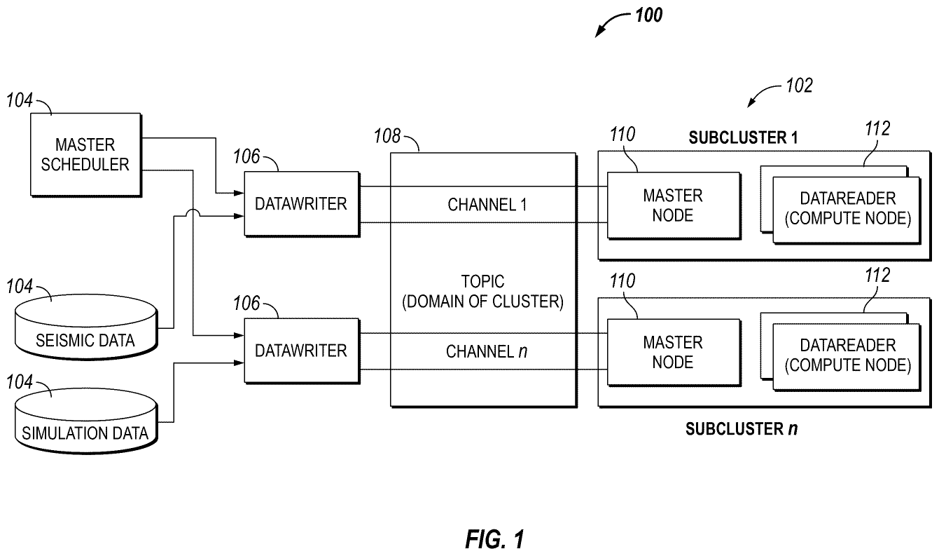

FIG. 1 depicts elements 100 of a HPC system that may implement a multi-channel QoS in accordance with an embodiment of the disclosure. The HPC system 100 has multiple subclusters, shown as n number of subclusters 102 (that is, subcluster 1 through subcluster n) shown in FIG. 1. The system 100 may include a master scheduler 104, datawriters 106, and communication channels 108 (that is, channel 1 through channel n). Each subcluster 102 includes a master node 110 and one or more datareaders (also referred to as a “compute node” or “processor node”) 112 operating as a network arranged for high performance or grid computing, depending on the configuration of the network, of exploration and production data. In the disclosure, the terms “publisher” and “publishing node” refers to and may be used interchangeably with the term “datawriter.” Additionally, the terms “computing node,” “processing node,” “subscriber,” and “subscribe node” refer to and are interchangeably with the term “datareader.” As described in the disclosure, the subclusters 102 may process exploration and production data with a specific multi-channel quality of service (QoS). The multi-channel QoS may be implemented in HPC platforms having elements 100, to circumvent the shortcomings of the currently used, de facto standard Message Passing Interface (MPI) and HPC Scheduling, and provide additional QoS for HPC applications. In some embodiments, the techniques described herein may be implemented for those applications in which QoS is considered a priority, there are multiple subclusters in the datacenter, and jobs should be distributed among them to lift up the overall utilization while preserving the QoS.

As controlled by the master scheduler 104, the datawriters 106 may send (“publish”) data using different multicast groups (that is, addresses) based on the data type, for example, seismic data 114 (for example, seismic survey of the earth in the reservoir), reservoir simulation data 116 (for example, a reservoir simulation model), and so on as shown in FIG. 1. Other data may include, for example, geological model of a reservoir. Data published by a datawriter 106 may be transferred through different communication channels 108 within the same topic of organization data (that is, an upstream data topic). Each subcluster 102 may be subscribed to a channel 108 to receive data for processing. Such data may be the seismic data 114, reservoir simulation data 116, or other data in a channel 108. The designated datawriter establishes a domain for exploration and production processing by a designated master node and designated processor nodes as subscriber processor nodes. A processor node 112 may be established as a subscriber to receive exploration and production data from the designated datawriter. The established quality of service (QoS) profile is transmitted from the designated datawriter to the subscriber processor node via the subcluster master node.

Embodiments of the disclosure may implement the quality of service (QoS) techniques here to manage large quantities and types of data; for example, in some embodiments, petabytes of data may be managed and may include upstream data mixed with stored seismic data and reservoir simulation data. The number of subclusters having datareaders may also be relatively large to facilitate processing of the data; however, each subcluster may only be interested in a subset of the available data at a given point in time. When data is sent, it may be passed through the filter expressions set by the master scheduler for all defined channels to determine whether it will be sent on a particular channel. Moreover, it may be possible for the same data to be sent on multiple channels. For example, if the same seismic or reservoir simulation data needs to be processed multiple times, the data may be sent on multiple channels. When a datareader is done processing, it may subscribe to a different channel through its master node of its subcluster to process another set of data.

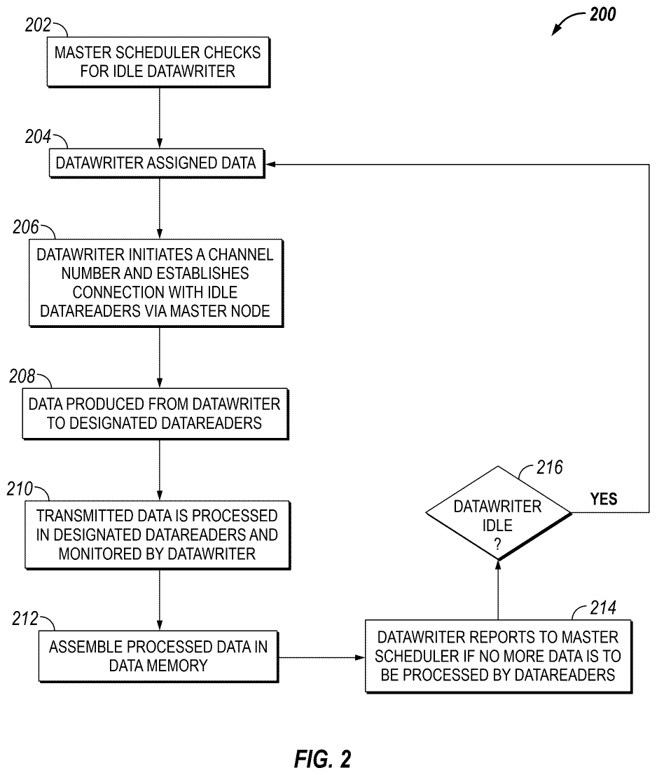

FIG. 2 depicts a process 200 for multi-channel quality of service (QoS) in accordance with an embodiment of the disclosure. Initially, the master scheduler checks for an idle datawriter (block 202); that is, a datawriter that is free with no data to be processed. After an idle datawriter is identified, the datawriter is assigned exploration and production data for processing (block 204).

In some embodiments, the master scheduler may check for an idle master node of a subcluster and select the subcluster with the free master node. As discussed herein, a datawriter communicates with a subcluster through the master node. A datawriter may send exploration and production to any subcluster that contains compute nodes (data readers) that is idle. It detects a free subcluster through the master node of that subcluster. As shown in FIG. 2, the datawriter initiates a channel number and establishes a connection with one or more datareaders of a subcluster via the master node of that subcluster (block 206). Thus, a communication channel is further established by designating a datareader (processor node) with same channel number as the datawriter. Establishing the connection may include establishing the quality of service (QoS) profile for the master node of the subcluster. The quality of service (QoS) profile includes a channel number and the designated master node of the plurality of master nodes, such that this master node is designated for the data being processed (that is, the master node is designated as a subscriber to the main publisher (datawriter)). When a datawriter establishes its channel with a datareader via the master node, it may also send other QoS settings, such as those defined in U.S. Pat. Nos. 8,874,804, 9,128,211, 9,429,677, 9,482,769, and 9,674,044.

Exploration and production data is then transmitted from the datawriter to the designated datareaders via the master node of the subcluster and the selected channel (block 208). The exploration and production data is processed in the designated datareaders of the subcluster and monitored by the datawriter (block 210). Additionally, a determination is made if the data being processed is real-time data. The processed exploration and production data received at the designated datareader is assembled in the data memory of the data processing system (212).

After the transmitting and processing of the exploration and production data is complete, the datawriter reports to the master scheduler that no more data is to be processed by the datareaders (block 214). If the datawriter is idle (decision block 216), the master scheduler may assign a new set of exploration and production data to the datawriter (block 204). The datawriter may then initiate a channel number, and establishes a connection with the requisite number of idle datareaders (block 206) to process the set of data through the subcluster master node.

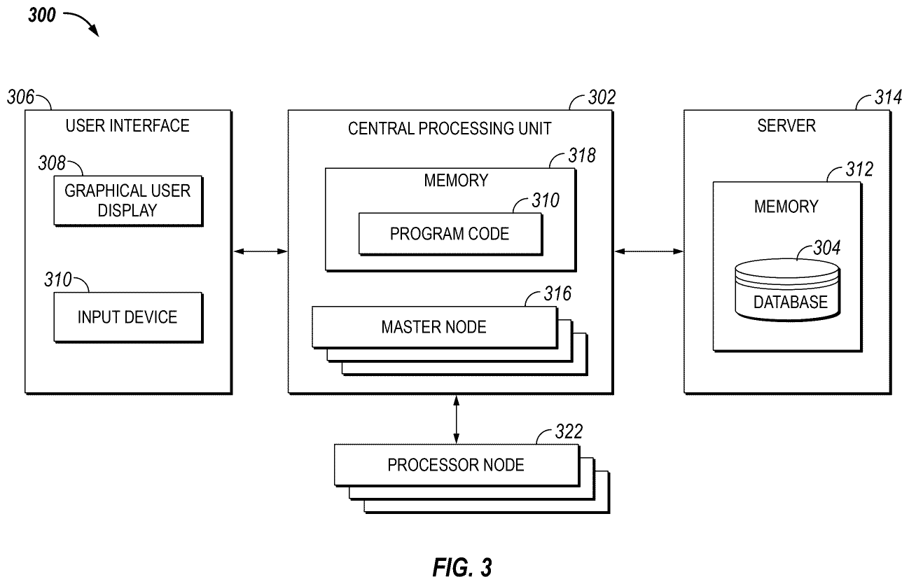

FIG. 3 depicts an example data processing system 300 for high performance computing (HPC) and grid computing of exploration and processing data in accordance with an embodiment of the disclosure. The data processing system 300 includes one or more central processing units or CPU's 302. The CPU or CPU's 302 have associated therewith a reservoir memory or database 304 for general input parameters, of a type and nature according to the exploration and production being processed, whether reservoir simulation, geological modeling, seismic data, or the like.

A user interface 306 operably connected with the CPU 302 includes a graphical display 308 for displaying graphical images, a printer or other suitable image forming mechanism and a user input device 310 to provide a user access to manipulate, access, and provide output forms of processing results, database records and other information.

The reservoir memory or database 304 is typically in a memory 312 of an external data storage server 314. The reservoir database 304 contains data including the structure, location, and organization of the cells in the reservoir model, data general input parameters, as well as the exploration and production data to be processed, as will be described below.

The CPU 302 of the data processing system 300 includes the master node 316 and an internal memory 318 coupled to master nodes 316 to store operating instructions, control information and to serve as storage or transfer buffers as required. The data processing system 300 may include program code 320 stored in memory 318. The program code 320, according to the present disclosure, is in the form of computer operable instructions causing the master node 316 and processor nodes 322 to communicate the exploration and production data and control instructions. As discussed herein, the master nodes 316 and processing nodes 322 may be arranged in subclusters processing data in accordance with the techniques described in the disclosure. As also discussed herein a master scheduler and datawriters (not shown) may be executed by the CPU 302 for communication with the master nodes 316 and processing nodes 322 as discussed herein.

It should be noted that program code 320 may be in the form of microcode, programs, routines, or symbolic computer operable languages that provide a specific set of ordered operations that control the functioning of the data processing system 300 and direct its operation. The instructions of program code 320 may be stored in memory 318 or on a solid state drive, magnetic tape, hard disk drive, electronic read-only memory, optical storage device, or other appropriate data storage device having a computer usable medium stored thereon. Program code 320 may also be contained on a data storage device as a computer readable medium.

The processor nodes 322 are general purpose, programmable data processing units programmed to perform the processing of exploration and production data according to the present disclosure. The processor nodes 322 operate under control of the master node 316 and the processing results obtained are then assembled in data memory 316 where the data are provided for formation with user interface 306 of output displays to form data records for analysis and interpretation.

Ranges may be expressed in the disclosure as from about one particular value, to about another particular value, or both. When such a range is expressed, it is to be understood that another embodiment is from the one particular value, to the other particular value, or both, along with all combinations within said range.

Further modifications and alternative embodiments of various aspects of the disclosure will be apparent to those skilled in the art in view of this description. Accordingly, this description is to be construed as illustrative only and is for the purpose of teaching those skilled in the art the general manner of carrying out the embodiments described in the disclosure. It is to be understood that the forms shown and described in the disclosure are to be taken as examples of embodiments. Elements and materials may be substituted for those illustrated and described in the disclosure, parts and processes may be reversed or omitted, and certain features may be utilized independently, all as would be apparent to one skilled in the art after having the benefit of this description. Changes may be made in the elements described in the disclosure without departing from the spirit and scope of the disclosure as described in the following claims. Headings used in the disclosure are for organizational purposes only and are not meant to be used to limit the scope of the description.

What is claimed is:

1. A method of computerized processing of data for exploration and production of hydrocarbons in a data processing system, the data processing system including a data memory, a plurality of subclusters, each of the plurality of subclusters having a respectively plurality of master nodes and a respective plurality of processor nodes that each receive data from the respectively plurality of master nodes, a plurality of publishing nodes, and a master scheduler, the method comprising:
identifying, via the master scheduler, an idle publishing node of the plurality of publishing nodes;
establishing a connection between the identified publishing node and a designated processor node of a select subcluster of the plurality of subclusters via a designated master node of the select subcluster, the establishing comprising initiating a channel number for a communication channel between the designated master node and the identified publishing node;
assigning, via the master scheduler, data to be processed to the identified publishing node;
transmitting the data from the identified publishing node to the designated processor node via the communication channel;
processing the data in the designated processor node;
transmitting the processed data to the designated master node; and
assembling in the data memory of the data processing system the processed data transmitted from the designated processor node.

2. The method of claim 1, comprising:
determining that no more data is to be processed by the designated processor node; and
reporting the determination to the master scheduler.

3. The method of claim 1, wherein the data comprises a reservoir simulation model.

4. The method of claim 1, wherein the data comprises a geological model of the reservoir.

5. The method of claim 1, wherein the data comprises a seismic survey of the earth in the reservoir.

6. The method of claim 1, wherein the data processing system further includes a data display, the method comprising:
forming an output display of the processed data.

7. The method of claim 1, wherein the designated processor node is established as a datareader for receiving and processing selected ones of different sets of the data as domains transmitted by the identified publishing node.

8. A data storage device having stored in a computer readable medium computer operable instructions for causing a data processing system to perform computerized processing of data for exploration and production of hydrocarbons, the data processing system including a data memory, a plurality of subclusters, each of the plurality of subclusters having a respectively plurality of master nodes and a respective plurality of processor nodes that each receive data from the respectively plurality of master nodes, a plurality of publishing nodes, and a master scheduler, the instructions stored in the data storage device causing the data processing system to perform operations comprising:
identifying, via the master scheduler, an idle publishing node of the plurality of publishing nodes;
establishing a connection between the identified publishing node and a designated processor node of a select subcluster of the plurality of subclusters via a designated master node of the select subcluster, the establishing comprising initiating a channel number for a communication channel between the designated master node and the identified publishing node;
assigning, via the master scheduler, data to be processed to the identified publishing node;
transmitting the data from the identified publishing node to the designated processor node via the communication channel;
processing the data in the designated processor node;
transmitting the processed data to the designated master node; and
assembling in the data memory of the data processing system the processed data transmitted from the designated processor node.

9. The data storage device of claim 8, the operations comprising:
determining that no more data is to be processed by the designated processor node; and
reporting the determination to the master scheduler.

10. The data storage device of claim 8, wherein the data comprises a reservoir simulation model.

11. The data storage device of claim 8, wherein the data comprises a geological model of the reservoir.

12. The data storage device of claim 8, wherein the data comprises a seismic survey of the earth in the reservoir.

13. The data storage device of claim 8, wherein the data processing system further includes a data display, the operations comprising:
forming an output display of the processed data.

14. The data storage device of claim 8, wherein the designated processor node is established as a datareader for receiving and processing selected ones of different sets of the data as domains transmitted by the identified publishing node.

15. A data processing system for computerized processing of data for exploration and production of hydrocarbons, the data processing system comprising:
a data memory;
a plurality of subclusters, each of the plurality of subclusters having a respectively plurality of master nodes and a respective plurality of processor nodes that each receive data from the respectively plurality of master nodes;
a plurality of publishing nodes;
a master scheduler; and
a computer readable medium comprising computer operable instructions for causing the data processing system to perform operations comprising:
identifying, via the master scheduler, an idle publishing node of the plurality of publishing nodes;
establishing a connection between the identified publishing node and a designated processor node of a select subcluster of the plurality of subclusters via a designated master node of the select subcluster, the establishing comprising initiating a channel number for a communication channel between the designated master node and the identified publishing node;
assigning, via the master scheduler, data to be processed to the identified publishing node;
transmitting the data from the identified publishing node to the designated processor node via the communication channel;
processing the data in the designated processor node;
transmitting the processed data to the designated master node; and
assembling in the data memory of the data processing system the processed data transmitted from the designated processor node.

16. The data storage system of claim 15, the operations comprising:
determining that no more data is to be processed by the identified processor node; and
reporting the determination to the master scheduler.

17. The data storage system of claim 15, wherein the data comprises a reservoir simulation model.

18. The data storage system of claim 15, wherein the data comprises a geological model of the reservoir.

19. The data storage system of claim 15, wherein the data comprises a seismic survey of the earth in the reservoir.

20. The data storage system of claim 15, wherein the data processing system further includes a data display, the operations comprising:
forming an output display of the processed data.

21. The data storage system of claim 15, wherein the designated processor node is established as a datareader for receiving and processing selected ones of different sets of the data as domains transmitted by the identified publishing node.
